(19) United States
(12) Patent Application Publication
(10) Pub. No.: US 2020/0064888 A1
(43) Pub. Date: Feb. 27, 2020

(54) ELECTRONIC DEVICE HOUSING

(71) Applicant: PEGATRON CORPORATION, Taipei City (TW)

(72) Inventors: Chan-Wei Kuo, Taipei City (TW); Hsiang-Chi Hsu, Taipei City (TW); I-Tien Hsieh, Taipei City (TW); Hui-Chen Wang, Taipei City (TW)

(73) Assignee: PEGATRON CORPORATION, Taipei City (TW)

(21) Appl. No.: 16/512,027

(22) Filed: Jul. 15, 2019

(30) Foreign Application Priority Data
Aug. 24, 2018 (TW) 107129693

(51) Int. Cl. G06F 1/16; H05K 5/02; H05K 5/03

(52) U.S. Cl. CPC G06F 1/1656; H05K 5/03; H05K 5/0217

(57) ABSTRACT

An electronic device housing includes a body and a protection cover. The body is provided with an opening; the protection cover and the body are integrally molded by injecting two or more materials; the protection cover is capable of shielding the opening; and the body has a first hardness, the protection cover has a second hardness, and the first hardness is different from the second hardness.

### CROSS-REFERENCE TO RELATED APPLICATION

This application claims the priority benefit of Taiwan application serial no. 107129693, filed on Aug. 24, 2018. The entirety of the above-mentioned patent application is hereby incorporated by reference herein and made a part of this specification.

### BACKGROUND

### Technology Field

The present invention relates to an electronic device housing, and more particularly to an electronic device housing capable of effectively preventing dust or vapor from entering interior.

### Description of Related Art

Generally, an electronic device such as a tablet computer or a laptop computer is additionally provided with a protection cover at a corresponding input/output port of the housing for shielding the input/output port. FIG. 1 is a schematic diagram showing a known protection cover assembled onto a housing of an electronic device by using screws. Referring to FIG. 1, a protection cover 20 is usually assembled onto a body 10 of an electronic device housing 1 by using an additional screw 30, so that an additional mold is required when manufacturing the protection cover 20. Moreover, an additional step is needed when the protection cover 20 is assembled onto the body 10 of the electronic device housing 1, so that time and labor are wasted, and the cost cannot be effectively saved.

Furthermore, the protection cover 20 and the body 10 are manufactured separately, resulting in a production deviation therebetween, so that a gap may be formed between the protection cover 20 and the opening of the body 10, and the dust or vapor might enter the electronic device housing 1 via the gap.

### SUMMARY

The present invention provides an electronic device housing capable of effectively preventing dust or vapor from entering interior.

The electronic device housing includes a body and a protection cover. The body is provided with an opening; the protection cover and the body are integrally molded by injecting two or more materials; the protection cover is capable of shielding the opening; and the body has a first hardness, the protection cover has a second hardness, and the first hardness is different from the second hardness.

In one embodiment of the present invention, the body is made of polycarbonate (PC) or polycarbonate and acrylonitrile-butadiene-styrene copolymer and a mixture (PCABS).

In one embodiment of the present invention, the protection cover is made of thermoplastic polyurethane (TPU) or thermoplastic elastomer.

In one embodiment of the present invention, the protection cover is provided with a connecting part, a rotation shaft, a cover body and a poking part; the cover body is capable of shielding the opening; the rotation shaft is connected between the connecting part and one side of the cover body; one side, which is not connected with the rotation shaft, of the connecting part is embedded into the body; and the poking part is protruded from a top surface of the cover body.

In one embodiment of the present invention, a thickness of the rotation shaft is smaller than the thickness of the connecting part.

In one embodiment of the present invention, the poking part is in a U shape.

In one embodiment of the present invention, the first hardness is greater than the second hardness.

Based on the above, the protection cover and the body are integrally molded by injecting two or more materials to form the electronic device housing; the material of the protection cover and the material of the body are different in softness or hardness; therefore, the protection cover and the opening are matched in shape and size so as to seal the opening of the body, thereby preventing the dust or vapor from entering the electronic device housing.

To make the foregoing features and advantages of the present invention more comprehensible, embodiments are described in detail below with the accompanying drawings.

### BRIEF DESCRIPTION OF THE DRAWINGS

FIG. 1 is a schematic diagram showing a known protection cover assembled onto a body of an electronic device housing by using screws.

FIG. 2 is a schematic diagram showing an electronic device housing according to embodiments of the present invention.

FIG. 3 is a side view of the electronic device housing of FIG. 2.

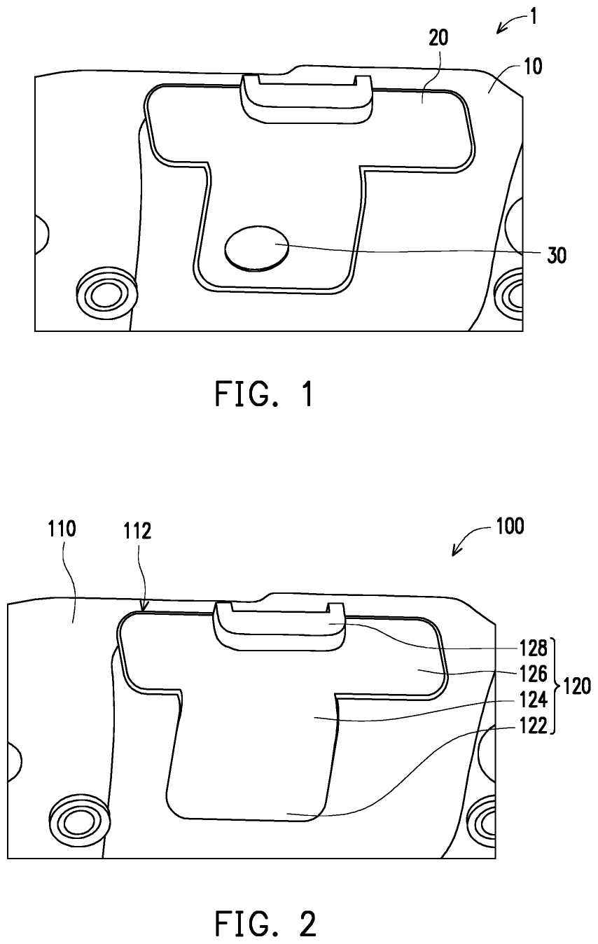

### DETAILED DESCRIPTION

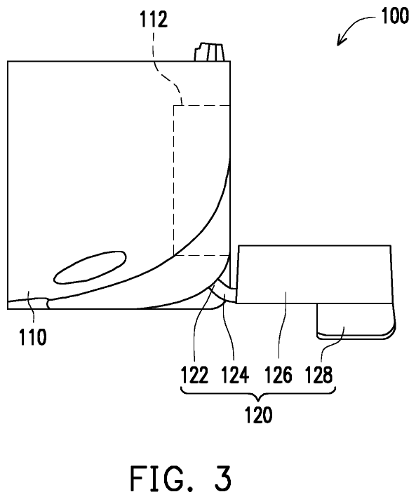

FIG. 2 is a schematic diagram showing an electronic device housing according to embodiments of the present invention, and FIG. 3 is a side view of the electronic device housing of FIG. 2. Referring to FIG. 2 and FIG. 3, the electronic device housing 100 includes a body 110 and a protection cover 120. The body 110 is provided with an opening 112; the protection cover 120 and the body 110 are integrally molded by injecting two or more materials; the protection cover 120 is capable of shielding the opening 112; and the body 110 has a first hardness while the protection cover 120 has a second hardness, and the first hardness is different from the second hardness. In embodiments of the present invention, the first hardness is greater than the second hardness, but not limited thereto, the first hardness might also be smaller than the second hardness.

The body 110 is made of a material having the first hardness, and the material having the first hardness and used for producing the body 110 is, for example, polycarbonate (PC), or polycarbonate and acrylonitrile-butadiene-styrene copolymer and a mixture (PCABS); and the protection cover 120 is made of a material having the second hardness, and the material having the second hardness and used for producing the protection cover 120 is, for example, thermoplastic polyurethane (TPU) or thermoplastic elastomer.

To be continued, the protection cover 120 is provided with a connecting part 122, a rotation shaft 124, a cover body 126 and a poking part 128; one side of the connecting part 122 is embedded into the body 110; the rotation shaft 124 is arranged between the connecting part 122 and the cover body 126; and the poking part 128 is protruded from a top surface of the cover body 126.

In detail, in an injection molding step, two different materials are successively injected into the same mold, so that the body 110 and the protection cover 120 are integrally formed by an injection molding.

In the molding process, the connecting part 122 is formed in the mold in a manner that one side of the connecting part is embedded into the body 110; and the rotation shaft 124 is formed in a manner that the thickness of the rotation shaft is smaller than the thickness of the connecting part 122 and the thickness of the cover body 126. Due to the small thickness of the rotation shaft 124, the cover body 126 for shielding the opening 112 can be rotated relative to the connecting part 122, using the rotation shaft 124 as a rotation axis.

Furthermore, the poking part 128 can be designed in a U shape or in an upside down U shape by virtue of a design mold, so that the poking part 128 can be easily poked by hands of a user, thereby driving the cover body 126 to be removed from the opening 112 of the body 110.

In addition, electronic components, for example, various connecting ports, might be disposed correspondingly inside the opening 112 of the body 110 of the electronic device chassis 100 or the opening 112 might be an earphone jack or a microphone jack set according to the requirements. Or, there might be no electronic components inside the opening 112, which is just an idle flexible space, and the flexible space is referred to as spare space where any electronic elements can be arranged by the user inside the opening 112 according to the requirements if necessary. Therefore, in an ordinary state, i.e. when the electronic elements arranged in the opening 112 are not in use, the opening 112 can be shielded by the protection cover 120 so as to prevent dust or water from entering the opening 112, thereby protecting the electronic elements arranged in the electronic device housing 100.

Referring to FIG. 2, the length, width and height of the opening 112 of the body 110 of the electronic device housing 100 may be slightly smaller than the length, width and height of the protection cover 120. When the protection cover 120 is arranged at the opening 112 the protection cover 120 is deformed by the press of the surrounding side walls and bottom wall of the opening 112 and tightly sealed to the opening 112 since the length, width and height of the opening 112 of the body 110 are slightly smaller than the length, width and height of the protection cover 120, and the protection cover 120 is made of the soft material when the cover body 126 of the protection cover 120 shields the opening 112, thereby preventing the dust or water from entering or permeating the electronic device via the opening 112 of the body 110.

Referring to FIG. 2 and FIG. 3, when the opening 112 is to be exposed, the user touches and presses the poking part 128 with fingers, which drives the cover body 126 connected with the poking part 128 to rotate relative to the connecting part 122 with the rotation shaft 124 as a rotation center, so that the cover body 126 is removed from the opening 112.

In addition, since the connecting part 122 and the body 110 are connected together, so that after the cover body 126 is removed from the opening 112, it is not necessary to worry that the protection cover 120 might be entirely detached from the body 110 and dropped off or be missing.

In general, in the electronic device housing of the present invention, the body and the protection cover are integrally molded by injecting two or more materials, and one side of the connecting part of the protection cover is embedded with the body, so that when the user removes the protection cover from the opening of the body, the protection cover can be prevented from entirely dropping off the body or be missing.

Moreover, the protection cover is made of the soft material, so the protection cover is deformed by the press of the side walls and the bottom wall of the opening and tightly sealed to the opening, thereby achieving an effect for preventing dust or water from entering or permeating the electronic device via the opening of the body.

Furthermore, since the protection cover and the body do not need screws for assembly, the assembling procedure and working hours can be saved, and the manpower can be applied to other places, thereby effectively saving the manpower cost.

Although the present invention is disclosed by using the foregoing embodiments, the embodiments are not intended to limit the present invention. Any persons of ordinary skill in the art can make some modifications and improvements without departing from the spirit and scope of the present invention. Therefore, the protection scope of the present invention is subject to the appended claims.

What is claimed is:

1. An electronic device housing, comprising:
a body with an opening; and
a protection cover integrally molded with the body by injecting two or more materials, wherein the protection cover is capable of shielding the opening, the body has a first hardness, the protection cover has a second hardness, and the first hardness is different from the second hardness.

2. The electronic device housing according to claim 1, wherein the body is made of polycarbonate or polycarbonate and acrylonitrile-butadiene-styrene copolymer and a mixture.

3. The electronic device housing according to claim 1, wherein the protection cover is made of thermoplastic polyurethane or thermoplastic elastomer.

4. The electronic device housing according to claim 1, wherein the protection cover is provided with a connecting part, a rotation shaft, a cover body and a poking part; the cover body is cable of shielding the opening; the rotation shaft is connected between the connecting part and one side of the cover body; one side, which is not connected with the rotation shaft, of the connecting part is embedded into the body; and the poking part is protruded from a top surface of the cover body.

5. The electronic device housing according to claim 4, wherein a thickness of the rotation shaft is smaller than a thickness of the connecting part.

6. The electronic device housing according to claim 1, wherein the poking part is in a U shape.

7. The electronic device housing according to claim 1, wherein the first hardness is greater than the second hardness.
